(19) United States
(12) Patent Application Publication
(10) Pub. No.: US 2014/0041902 A1
(43) Pub. Date: Feb. 13, 2014

(54) PRINTED CIRCUIT BOARD AND METHOD OF MANUFACTURING THE SAME

(71) Applicant: SAMSUNG ELECTRO-MECHANICS CO., LTD., Gyunggi-do (KR)

(72) Inventors: Jeong Woo Lee, Gyunggi-do (KR); Going Sik Kim, Gyunggi-do (KR)

(73) Assignee: SAMSUNG ELECTRO-MECHANICS CO., LTD., Gyunggi-do (KR)

(21) Appl. No.: 13/681,598

(22) Filed: Nov. 20, 2012

(30) Foreign Application Priority Data
Aug. 7, 2012 (KR) 10-2012-0086288

(51) Int. Cl. H05K 1/02; G03F 7/20

(52) U.S. Cl. CPC H05K 1/0284; G03F 7/2022
USPC 174/251; 430/319

(57) ABSTRACT

Disclosed herein is a printed circuit board, including: a base substrate on which a circuit layer is formed; and multi-layer insulating layers formed in a plurality of layers on the base substrate, including the circuit layer, each of the plurality of layers being formed to have a step structure, wherein the multi-layer insulating layer is formed of heterogeneous materials.

### CROSS REFERENCE TO RELATED APPLICATION

This application claims the benefit of Korean Patent Application No. 10-2012-0086288, filed on Aug. 7, 2012, entitled “Printed Circuit Board And Method Of Manufacturing The Same”, which is hereby incorporated by reference in its entirety into this application.

### BACKGROUND OF THE INVENTION

1. Technical Field

The present invention relates to a printed circuit board and a method of manufacturing the same.

2. Description of the Related Art

Recently, electronic industries have positively used various materials for miniaturization and slimness of electronic devices and attempts to improve reliability and productivity of functional materials have been actively conducted.

Therefore, a printed circuit board including one described in Patent Document 1 is variously designed and is formed of various materials so as to improve reliability of product.

Meanwhile, a solder resist serves to prevent a solder from being unnecessarily attached to a portion of an outermost layer of a substrate and protect a circuit on an outermost layer.

Recently, in order to improve reliability and productivity according to various configuration of layers and product characteristics, the solder resist also requires many functional characteristics.

### RELATED ART DOCUMENT

### Patent Document

(Patent Document 1) US2006-0191709 A

### SUMMARY OF THE INVENTION

The present invention has been made in an effort to a printed circuit board and a method of manufacturing the same capable of improving manufacturing reliability of a printed circuit board by forming an insulating layer of two or more insulating materials having different photosensitive sensitivities.

According to a preferred embodiment of the present invention, there is provided a method of manufacturing a printed circuit board, including: preparing a base substrate on which a circuit layer is formed; forming a multi-layer insulating layer formed in a plurality of layers on the base substrate, including the circuit layer, each of the plurality of layers being formed of heterogeneous materials; and forming a step structure on the multi-layer insulating layer by performing exposing and developing processes on each of the plurality of layers of the multi-layer insulating layer.

Each of the plurality of layers of the multi-layer insulating layer may be formed of heterogeneous materials having different developing selectivities, and in the forming of the step structure, each of the plurality of layers of the multi-layer insulating layer may be subjected to the develop process by differently applying conditions of a developer based on the developing selectivity of the corresponding insulating layer.

Each of the plurality of layers of the multi-layer insulating layer may be formed of a negative type photoresist of heterogeneous materials.

Each of the plurality of layers of the multi-layer insulating layer may be formed of heterogeneous materials having different exposure selectivities, and in the forming of the step structure, each of the plurality of layers of the multi-layer insulating layer may be subjected to the exposing process by differently applying conditions of a light quantity based on the exposure selectivity of the corresponding insulating layer.

Each of the plurality of layers of the multi-layer insulating layer may be formed of a positive type photoresist of heterogeneous materials.

In the forming of the step structure, the step structure of the multi-layer insulating layer may have a shape in which a width of the opening parts of each of the plurality of layers is narrow toward the base substrate side from an upper surface of the multi-layer insulating layer.

According to another preferred embodiment of the present invention, there is provided a printed circuit board, including: a base substrate on which a circuit layer is formed; and multi-layer insulating layers formed in a plurality of layers on the base substrate, including the circuit layer, each of the plurality of layers being formed to have a step structure, wherein the multi-layer insulating layer is formed of heterogeneous materials.

Each of the plurality of layers of the multi-layer insulating layer may be formed of heterogeneous materials having different exposure selectivities.

Each of the plurality of layers of the multi-layer insulating layer may be formed of heterogeneous materials having different developing selectivities.

Each of the plurality of layers of the multi-layer insulating layer may be formed of a photoresist of heterogeneous materials.

The step structure of the multi-layer insulating layer may have a shape in which a width of the opening parts of each of the plurality of layers is narrow toward the base substrate side from an upper surface of the multi-layer insulating layer.

### BRIEF DESCRIPTION OF THE DRAWINGS

The above and other objects, features and advantages of the present invention will be more clearly understood from the following detailed description taken in conjunction with the accompanying drawings, in which:

FIGS. 1 to 8 are cross-sectional views for sequentially describing the process of manufacturing a printed circuit board according to a first preferred embodiment of the present invention.

FIGS. 9 to 14 are cross-sectional views for sequentially describing the process of manufacturing a printed circuit board according to a second preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Method of Manufacturing Printed Circuit Board

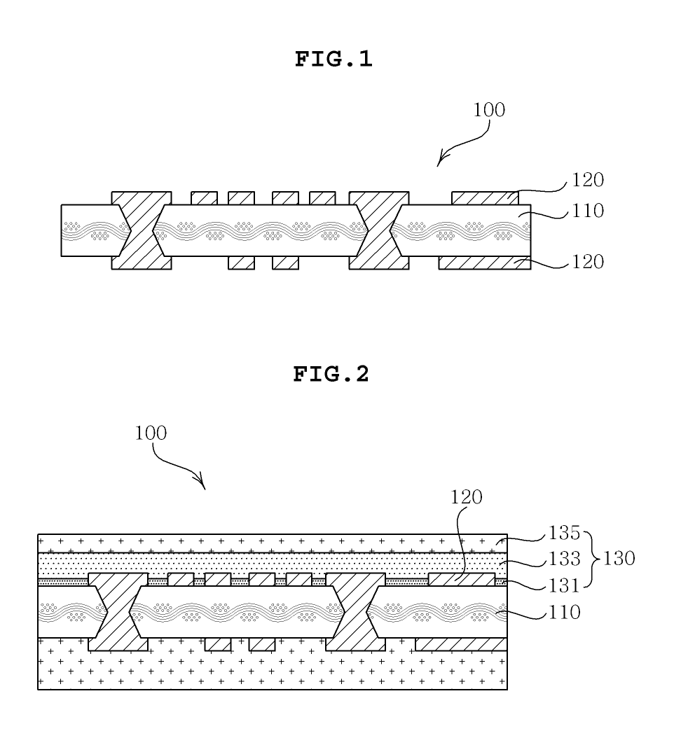

FIGS. 1 to 8 are cross-sectional views for sequentially describing the process of manufacturing a printed circuit board according to a first preferred embodiment of the present invention.

First, as shown in FIG. 1, a base substrate 110 on which a circuit layer 120 is formed may be prepared.

The base substrate 110 may be a general insulating layer used as a core substrate in a printed circuit board field or may be a printed circuit board 100 on which a circuit including a circuit layer 120 having a connection pad of at least one layer is formed.

As the insulating layer, a resin insulating layer may be used. As the resin insulating layer, a thermosetting resin such as epoxy resin, a thermoplastic resin such as polyimide, resin having reinforcing materials such as a glass fiber or an inorganic filler impregnated thereinto, for example, prepreg, and the like, may be used. In addition, thermosetting resin and/or photocurable resin, and the like, may be used, but the exemplary embodiment of the present invention is not particularly limited thereto.

Next, as shown in FIG. 2, multi-layer insulating layers 130, 131, 133, and 135 that are formed in a plurality of layers on the base substrate 110, including the circuit layer 120 may be formed, wherein each of the plurality of layers is formed of heterogeneous materials.

Each of the plurality of layers of the multi-layer insulating layers 130, 131, 133, and 135 may be formed of heterogeneous materials having different developing selectivities.

In addition, each of the plurality of layers of the multi-layer insulating layers 130, 131, 133, and 135 may be formed of a negative type photoresist of hetereogeneous materials.

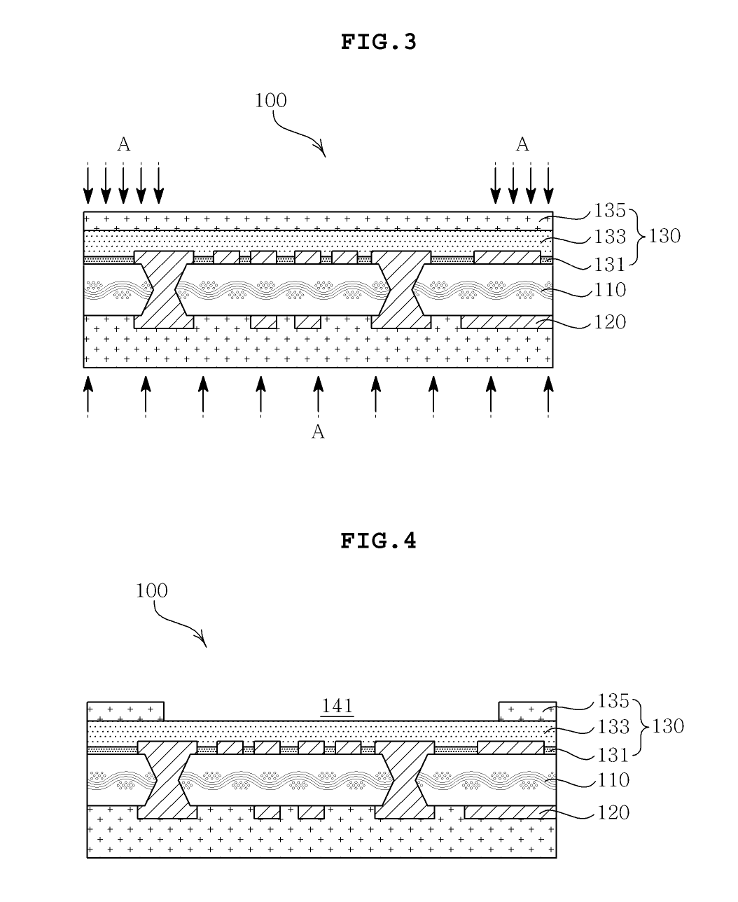

As shown in FIGS. 3 to 8, the multi-layer insulating layer 130 may be formed of the negative type photoresist of which the non-cured area other than an area subjected to exposure A is removed by a developer.

For example, the negative type photoresist of the heterogeneous materials may be a resin compound having different reactivity with respect to inorganic alkali such as Na2CO3, and the like or two or more photoresist adhesives having relative reactivity with respect to a developer having different solution compositions.

Next, as shown in FIGS. 3 to 8, each of the plurality of layers of the multi-layer insulating layers 130, 131, 133, and 135 is subjected to exposing and developing processes, such that the multi-layer insulating layers 130, 131, 133, and 135 may have a step structure.

In this case, each of the plurality of layers of the multi-layer insulating layer 130 may be subjected to the developing process by differently applying conditions of the developer based on the developing selectivity of the corresponding insulating layer.

The developing selectivity is defined as meaning reaction conditions (that is, the sensitivity to the developer) to the developer.

As shown in FIGS. 3 and 4, an outermost layer 135 among the multi-layer insulating layers 131, 133, and 135 is subjected to the exposing (A of FIG. 3) and developing processes, thereby forming an opening part 141.

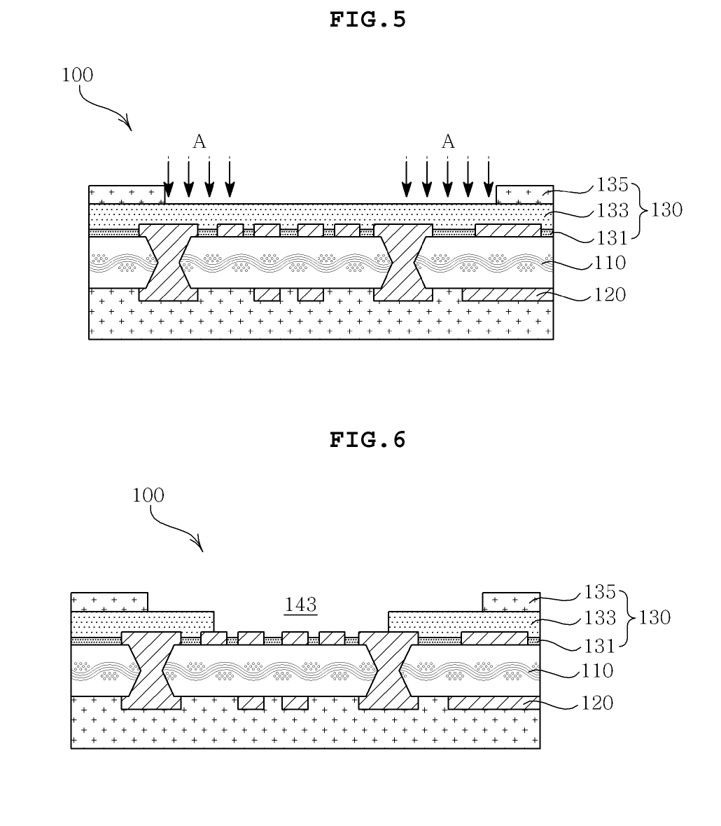

Next, as shown in FIGS. 5 and 6, a portion of the multi-layer insulating layer 133 exposed through the opening part 141 is subjected to the exposing (A of FIG. 5) and developing processes, thereby forming the opening part 143.

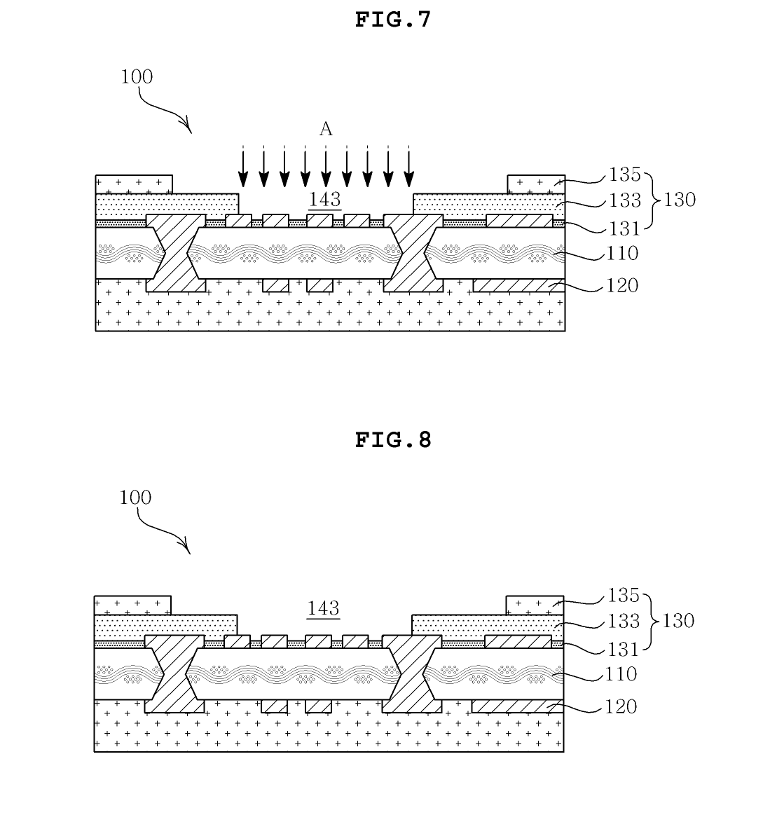

Next, as shown in FIGS. 7 and 8, the multi-layer insulating layer 131 exposed through the opening part 143 may be cured by being subjected to the exposure (A of FIG. 7).

In FIGS. 3 to 8, the exposed and cured area among the multi-layer insulating layers 131, 133, and 135 has a different hardness of a material from a non-cured state to a cured state, but for convenience of explanation, the change of a material is not shown.

The opening part 141 is formed to be larger than the opening part 143 based on a length direction of the printed circuit board 100, such that the multi-layer insulating layer 130 may have a step structure.

That is, as shown in FIG. 8, in the forming of the step structure, the step structure of the multi-layer insulating layer 130 may have a shape in which a width of the opening parts (141 of FIGS. 4 and 143 of FIG. 8) of each of the plurality of layers is narrow toward the base substrate 110 side from an upper surface of the multi-layer insulating layer 130.

Meanwhile, a solder ball as an external connection terminal is formed on the connection pad of the circuit layer 120 by a subsequent process and a semiconductor device or external components and an inner-layer circuit are electrically connected by the solder ball.

The circuit including the connection pad may be applied without being limited if a conductive metal for a circuit may be used in the printed circuit board field. Typically, copper may be used in the printed circuit board.

The exposed connection pad may be further formed with a surface treating layer (not shown), if necessary.

Any surface treating layer known to those skilled in the art may be used without being particularly limited. For example, the surface treating layer may be formed by electro gold plating, immersion gold plating, organic solderability preservative (OSP), immersion tin plating, immersion silver plating, electroless nickel and immersion gold (ENIG), direct immersion gold (DIG) plating, hot air solder leveling (HASL), and the like.

When the multi-layer insulating layer 130 is applied as the photoresist negative type, a portion of the non-cured photoresist may be subjected to a partial developing according to the foregoing process. A method of controlling a developing process controls a developer based on a material of the corresponding layer to be developed. In this case, each of the plurality of layers of the multi-layer insulating layer 130 is formed of a material having different developing selectivity, thereby implementing fine adjustment at the time of patterning.

Further, the preferred embodiment of the present invention uses photosensitive insulating materials having different developing selectivities to prevent a cracking phenomenon due to a penetration of chemical into an interface between the circuit layer 120 and the multi-layer insulating layer 130.

In addition, the multi-layer insulating layer 130 of heterogeneous materials having the step structure of the preferred embodiment of the present invention may implement the fine patterning and improving alignment.

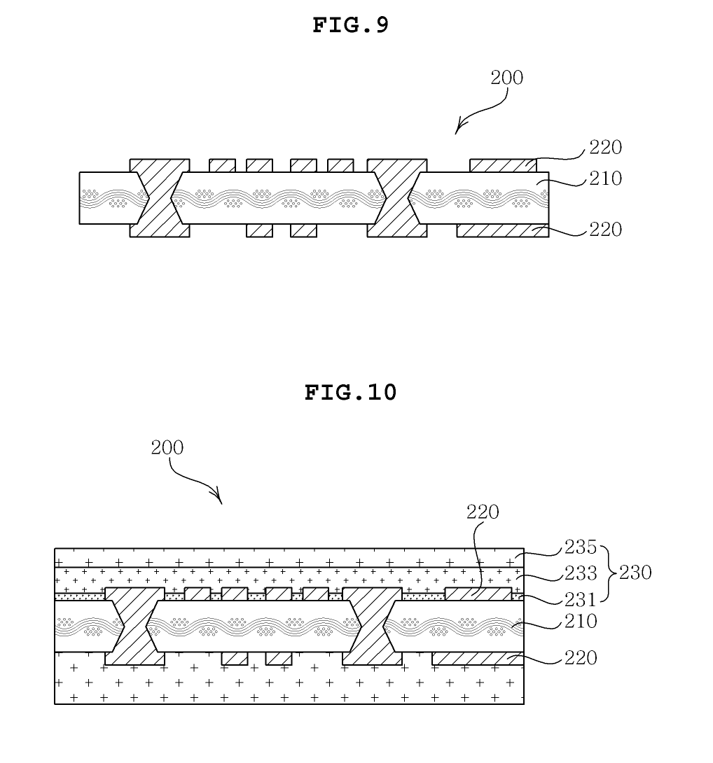

FIGS. 9 to 14 are process cross-sectional views for describing a method of manufacturing a printed circuit board according to a second preferred embodiment of the present invention.

First, as shown in FIG. 9, a base substrate 210 on which a circuit layer 220 is formed may be prepared.

The base substrate 210 may be a general insulating layer used as a core substrate in a printed circuit board field or may be a printed circuit board 200 on which a circuit including a circuit layer 220 having a connection pad of at least one layer is formed.

As the insulating layer, a resin insulating layer may be used. As the resin insulating layer, a thermosetting resin such as epoxy resin, a thermoplastic resin such as polyimide, resin having reinforcing materials such as a glass fiber or an inorganic filler impregnated thereinto, for example, prepreg, and the like, may be used. In addition, thermosetting resin and/or photocurable resin, and the like, may be used, but the exemplary embodiment of the present invention is not particularly limited thereto.

Next, as shown in FIG. 10, multi-layer insulating layers 230, 231, 233, and 235 that are formed in a plurality of layers on the base substrate 210, including the circuit layer 220 may be formed, wherein each of the plurality of layers is formed of heterogeneous materials.

Each of the plurality of layers of the multi-layer insulating layers 230, 231, 233, and 235 may be formed of heterogeneous materials having different exposure selectivities.

In addition, each of the plurality of layers of the multi-layer insulating layers 230, 231, 233, and 235 may be formed of a positive type photoresist of heterogeneous materials.

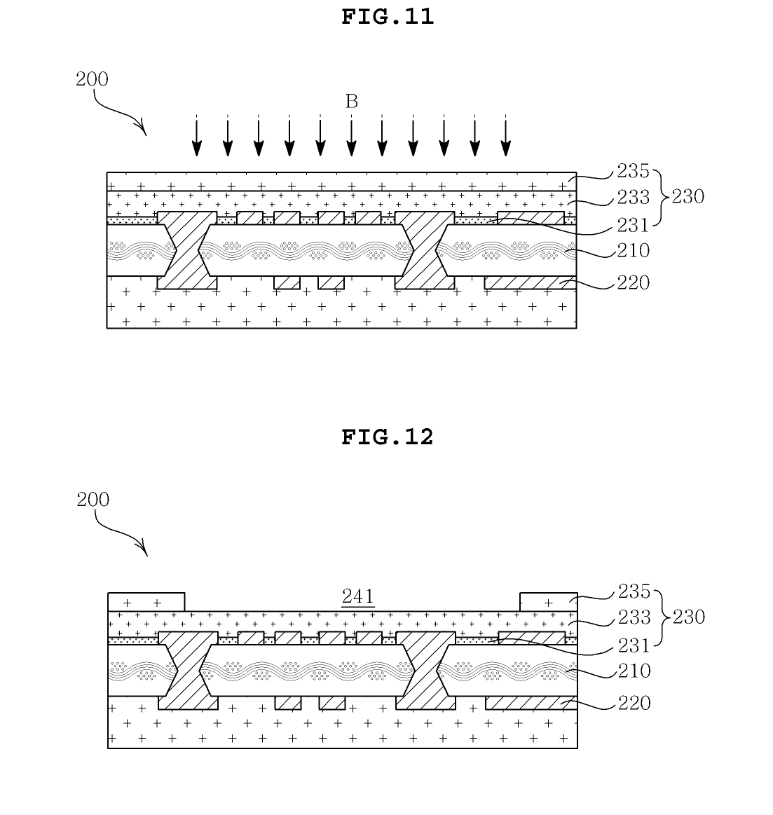

As shown in FIGS. 11 to 14, the multi-layer insulating layer 230 may be formed of the positive type photoresist in which an area subjected to exposure B is removed by a developer.

For example, the positive type photoresist of heterogeneous materials may use materials having different α-Rays, exposure sensitivities, or absorbance wavelengths by changing a photoinitiator, a filler, and the like.

Next, as shown in FIGS. 11 to 14, each of the plurality of layers of the multi-layer insulating layers 230, 231, 233, and 235 is subjected to exposing and developing processes, such that the multi-layer insulating layers 230, 231, 233, and 235 may have a step structure.

In this case, each of the plurality of layers of the multi-layer insulating layer 230 may be subjected to the exposing process by differently applying conditions of a light quantity based on the exposure selectivity of the corresponding insulating layer.

The exposure selectivity is defined as meaning reaction conditions (that is, the sensitivity to the exposure) to the exposure.

As shown in FIGS. 11 and 12, an outermost layer 235 among the multi-layer insulating layers 231, 233, and 235 is subjected to the exposing (B of FIG. 11) and developing processes, thereby forming an opening part 241.

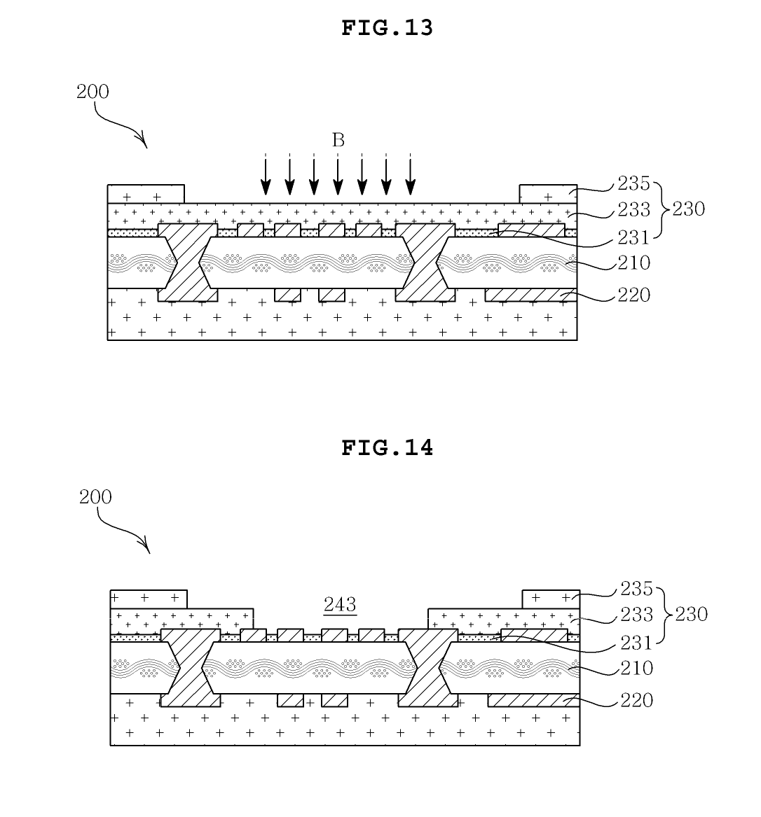

Next, as shown in FIGS. 13 and 14, a portion of the multi-layer insulating layer 233 exposed through the opening part 241 is subjected to the exposing (B of FIG. 13) and developing processes, thereby forming the opening part 243.

The opening part 241 is formed to be larger than the opening part 243 based on a length direction of the printed circuit board 200, such that the multi-layer insulating layer 230 may have a step structure.

That is, as shown in FIG. 14, in the forming of the step structure, the step structure may have a shape in which a width of the opening parts (241 of FIGS. 12 and 243 of FIG. 14) of each of the plurality of layers is narrow toward the base substrate 210 side from an upper surface of the multi-layer insulating layer 230.

Meanwhile, a solder ball as an external connection terminal is formed on the connection pad of the circuit layer 220 by a subsequent process and a semiconductor device or external components and an inner-layer circuit are electrically connected by the solder ball.

The circuit including the connection pad may be applied without being limited if a conductive metal for a circuit may be used in the printed circuit board field. Typically, copper may be used in the printed circuit board.

The exposed connection pad may be further formed with a surface treating layer (not shown), if necessary.

Any surface treating layer known to those skilled in the art may be used without being particularly limited. For example, the surface treating layer may be formed by electro gold plating, immersion gold plating, organic solderability preservative (OSP), immersion tin plating, immersion silver plating, electroless nickel and immersion gold (ENIG), direct immersion gold (DIG) plating, hot air solder leveling (HASL), and the like.

When the multi-layer insulating layer 230 is applied as the photoresist positive type, a portion of the photoresist may be subjected to a partial exposure according to the foregoing process. The preferred embodiment of the present invention performs the partial exposure by controlling the light quantity according to the photosensitive characteristic of the photoresist at the time of exposure. In this case, each of the plurality of layers of the multi-layer insulating layer 230 is formed of materials having different exposure selectivities, thereby more improving the process reliability of the multi-layer insulating layer 230.

Further, the preferred embodiment of the present invention uses photosensitive insulating materials having different exposure selectivities to prevent a cracking phenomenon due to a penetration of chemical into an interface between the circuit layer 220 and the multi-layer insulating layer 230.

In addition, the multi-layer insulating layer 130 of heterogeneous materials having the step structure of the preferred embodiment of the present invention may implement the fine patterning, thereby improving alignment.

Printed Circuit Board

FIGS. 1 to 8 are cross-sectional views for sequentially describing the process of manufacturing a printed circuit board according to a first preferred embodiment of the present invention and FIGS. 9 to 14 are cross-sectional views for sequentially describing the process of manufacturing a printed circuit board according to a second preferred embodiment of the present invention.

As shown in FIGS. 8 and 14, the printed circuit board 100 includes the base substrates 110 and 210 on which the circuit layers 120 and 220 are formed and the multi-layer insulating layers 130, 131, 133, 135, 230, 231, 233, and 235 formed in a plurality of layers on the base substrates 110 and 210, including the circuit layers 120 and 220, wherein each of the plurality of layers has a step structure.

In this configuration, each of the multi-layer insulating layers 130, 131, 133, 135, 230, 231, 233, and 235 may be formed of heterogeneous materials.

Meanwhile, each of the plurality of layers of the multi-layer insulating layers 230, 231, 233, and 235 may be formed of heterogeneous materials having different exposure selectivities.

On the other hand, each of the plurality of layers of the multi-layer insulating layers 130, 131, 133, and 135 may be formed of heterogeneous materials having different developing selectivities.

Each of the multi-layer insulating layers 130, 131, 133, 135, 230, 231, 233, and 235 may be formed of the photoresist of heterogeneous materials.

As shown in FIGS. 8 and 14, the step structure of the multi-layer insulating layers 130, 131, 133, 135, 230, 231, 233, and 235 may have a shape in which a width of the opening parts of each of the plurality of layers is narrow toward the base substrates 110 and 210 sides from an upper surfaces of the multi-layer insulating layers 130, 131, 133, 135, 230, 231, 233, and 235.

According to the printed circuit board and the method of manufacturing the same of the preferred embodiments of the present invention, each of the multi-layer insulating layers can be formed of the heterogeneous photosensitive insulating materials to previously prevent the problems from occurring at the interface between the circuit layer and the insulating layer upon forming the step structure on the insulating layer of the outermost layer, thereby making it possible to improve the productivity and reliability of the printed circuit board.

Further, according to the preferred embodiments of the present invention, it is possible to finely implement the multi-step solder resist having the step structure without degrading the productivity when using the photoresist adhesives of two or more materials and to improve the alignment.

Although the preferred embodiments of the present invention have been disclosed for illustrative purposes, they are for specifically explaining the present invention and thus a printed circuit board and a method Of manufacturing the Same according to the present invention is not limited thereto, but those skilled in the art will appreciate that various modifications, additions and substitutions are possible, without departing from the scope and spirit of the invention as disclosed in the accompanying claims.

Accordingly, any and all modifications, variations or equivalent arrangements should be considered to be within the scope of the invention, and the detailed scope of the invention will be disclosed by the accompanying claims.

What is claimed is:

1. A method of manufacturing a printed circuit board, comprising:
preparing a base substrate on which a circuit layer is formed;
forming a multi-layer insulating layer formed in a plurality of layers on the base substrate, including the circuit layer, each of the plurality of layers being formed of heterogeneous materials; and
forming a step structure on the multi-layer insulating layer by performing exposing and developing processes on each of the plurality of layers of the multi-layer insulating layer.

2. The method as set forth in claim 1, wherein each of the plurality of layers of the multi-layer insulating layer is formed of heterogeneous materials having different developing selectivities, and
in the forming of the step structure, each of the plurality of layers of the multi-layer insulating layer is subjected to the develop process by differently applying conditions of a developer based on the developing selectivity of the corresponding insulating layer.

3. The method as set forth in claim 2, wherein each of the plurality of layers of the multi-layer insulating layer is formed of a negative type photoresist of heterogeneous materials.

4. The method as set forth in claim 1, wherein each of the plurality of layers of the multi-layer insulating layer is formed of heterogeneous materials having different exposure selectivities, and
in the forming of the step structure, each of the plurality of layers of the multi-layer insulating layer is subjected to the exposing process by differently applying conditions of a light quantity based on the exposure selectivity of the corresponding insulating layer.

5. The method as set forth in claim 4, wherein each of the plurality of layers of the multi-layer insulating layer is formed of a positive type photoresist of heterogeneous materials.

6. The method as set forth in claim 1, wherein in the forming of the step structure, the step structure of the multi-layer insulating layer has a shape in which a width of the opening parts of each of the plurality of layers is narrow toward the base substrate side from an upper surface of the multi-layer insulating layer.

7. A printed circuit board, comprising:
a base substrate on which a circuit layer is formed; and
multi-layer insulating layers formed in a plurality of layers on the base substrate, including the circuit layer, each of the plurality of layers being formed to have a step structure,
wherein the multi-layer insulating layer is formed of heterogeneous materials.

8. The printed circuit board as set forth in claim 7, wherein each of the plurality of layers of the multi-layer insulating layer is formed of heterogeneous materials having different exposure selectivities.

9. The printed circuit board as set forth in claim 7, wherein each of the plurality of layers of the multi-layer insulating layer is formed of heterogeneous materials having different developing selectivities.

10. The printed circuit board as set forth in claim 7, wherein each of the plurality of layers of the multi-layer insulating layer is formed of a photoresist of heterogeneous materials.

11. The printed circuit board as set forth in claim 7, wherein the step structure of the multi-layer insulating layer has a shape in which a width of opening parts of each of the plurality of layers is narrow toward the base substrate side from an upper surface of the multi-layer insulating layer.
